(19) United States
(12) Patent Application Publication
(10) Pub. No.: US 2009/0146314 A1
(43) Pub. Date: Jun. 11, 2009

(54) Semiconductor Device

(75) Inventors: Sadakazu Akaike, Nagano-shi (JP); Atsunori Kajiki, Nagano-shi (JP); Takashi Tsubota, Nagano-shi (JP); Norio Yamanishi, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/267,649

(22) Filed: Nov. 10, 2008

(30) Foreign Application Priority Data
Dec. 7, 2007 (JP) 2007-316698

(51) Int. Cl. H01L 23/52

(52) U.S. Cl. 257/777; 257/E23.141

(57) ABSTRACT

A semiconductor device includes a first wiring board having a semiconductor element connection pad; a semiconductor element connected to the semiconductor element connection pad; and a second wiring board facing the semiconductor element and the first wiring board, the second wiring board being electrically connect to the first wiring board. The semiconductor element includes an electrode configured to electrically connect a first surface of the semiconductor element and a second surface of the semiconductor element to each other. The first surface of the semiconductor element faces the first wiring board. The second surface of the semiconductor element faces the second wiring board. The first wiring board and the second wiring board are electrically connected to each other via the electrode.

### BACKGROUND OF THE INVENTION

1. Field of the Invention

The present invention generally relates to semiconductor devices. More specifically, the present invention relates to a semiconductor device including a first wiring board, a semiconductor element connected to the first wiring board, and a second wiring board facing the first wiring board and the semiconductor element, the second wiring board being electrically connected to the first wiring board.

2. Description of the Related Art

A semiconductor device having a first wiring board, a semiconductor element connected to the first wiring board, and a second wiring board facing the first wiring board and the semiconductor element, the second wiring board being electrically connected to the first wiring board, has been suggested (see FIG. 1).

FIG. 1 is a cross-sectional view of a related art semiconductor device.

Referring to FIG. 1, a semiconductor device 300 includes a first wiring board 301, semiconductor elements 302 and 306, outside connection terminals 303, a second wiring board 305, electronic components 307, inside connection terminals 309, and sealing resin 311 and 312.

The first wiring board 301 is a built-up board having a core. The first wiring board 301 includes a core board 315, an insulation layer 316, an insulation layer 317, semiconductor element connection pads 318, inside connection pads 321, outside connection pads 323 and 324, and wiring patterns 326 and 327. The insulation layer 316 is formed on an upper surface 315A of the core board 315. The insulation layer 317 is formed on a lower surface 315B of the core board 315.

The semiconductor element connection pads 318 are provided on a portion of an upper surface 316A of the insulation layer 316, the portion corresponding to the center part of the first wiring board 301. The inside connection pads 321 are provided on a portion of the upper surface 316A of the insulation layer 316, the portion corresponding to external circumferential parts of the first wiring board 301. The outside connection pads 323 and 324 are provided on a lower surface 317A of the insulation layer 317.

The wiring pattern 326 pierces the core board 315 and the insulation layers 316 and 317. The wiring pattern 326 includes via-plugs and wirings provided in the insulation layers 316 and 317 and a piercing via-plug which pierces the core board 315. The wiring patterns 326 are connected to the inside connection pads 321 and the outside connection pads 324. Thus, the inside connection pads 321 are electrically connected to the outside connection pads 324.

The wiring patterns 327 pierce the core board 315 and the insulation layers 316 and 317. The wiring pattern 327 includes the via-plugs and wirings provided in the insulation layers 316 and 317 and a piercing via-plug piercing the core board 315. The wiring patterns 327 are connected to the semiconductor element connection pads 318 and the outside connection pads 323. Thus, the semiconductor element connection pads 318 are electrically connected to the outside connection pads 323.

The semiconductor element 302 is flip-chip connected to the semiconductor element connection pads 318. The outside connection terminals 303 are provided on the outside connection pads 323 and 324. The outside connection terminals 303 are electrically connected to pads (not illustrated in FIG. 1) provided on a mounting board such as a motherboard.

The second wiring board 305 is a built-up board having a core. The second wiring board 305 includes a core board 331, an insulation layer 332, an insulation layer 333, wiring patterns 336, 337, 341, and 342, and inside connection pads 338. The insulation layer 332 is formed on an upper surface 331A of the core board 331. The insulation layer 333 is formed on a lower surface 331B of the core board 331.

The wiring patterns 336 and 337 are provided on the upper surface 332A of the insulation layer 332. The wiring pattern 336 includes a pad where a metal wire 345 electrically connected to the semiconductor element 306 is connected and a pad where the electronic component 307 is connected. The wiring pattern 337 includes a pad where the electronic component 307 is connected.

The inside connection pads 338 are provided on a lower surface 333A of the insulation layer 333. The inside connection terminals 309 are provided on the inside connection pads 338. The inside connection terminals 309 electrically connect the first wiring board 301 and the second wiring board 305 to each other.

The wiring pattern 341 pierces the core board 331 and the insulation layers 332 and 333. The wiring pattern 341 includes via-plugs and wirings provided in the insulation layers 332 and 333 and a piercing via-plug which pierces the core board 331. The wiring patterns 341 are connected to the wiring patterns 337 and the outside connection pads 338. Thus, the wiring patterns 337 are electrically connected to the inside connection pads 338.

The wiring patterns 342 pierce the core board 331 and the insulation layers 332 and 333. The wiring pattern 342 includes via-plugs and wirings provided in the insulation layers 332 and 333 and a piercing via-plug piercing the core board 331. The wiring patterns 342 are connected to the wiring patterns 336 and the inside connection pads 338. Thus, the wiring patterns 336 are electrically connected to the inside connection pads 338.

The semiconductor element 306 is adhered on the upper surface 332A of the insulation layer 332. The semiconductor element 306 is connected to the metal wires 345. The semiconductor element 306 is electrically connected to the wiring patterns 336 via the metal wires 345. The electronic components 307 are connected to the wiring patterns 336 and 337.

The inside connection terminals 309 are provided between the inside connection pads 321 provided on the first wiring board 301 and the inside connection pads 338 provided on the second wiring board 305. The inside connection terminals 309 form a gap between the first wiring board 301 and the second wiring board 305 so that the semiconductor element 302 can be received in the gap. The inside connection terminals 309 electrically connect the first wiring board 301 and the second wiring board 305 to each other. A solder ball, a conductive core ball or the like may be used as the inside connection terminal 309. The conductive core ball includes a core part and a covering part covering the core part. The height of the inside connection terminal 309 provided between the first wiring board 301 and the second wiring board 305 may be, for example, 300 μm.

The sealing resin 311 is provided so as to fill the gap between the first wiring board 301 and the second wiring board 305. The sealing resin 311 seals the semiconductor element 302 and the inside connection terminals 309. The sealing resin 312 is provided on the upper surface 332A of the insulation layer 332 so as to seal the semiconductor element 306, the electronic components 307, and the metal wires 345 (see, for example, International Publication No. 07/069,606).

However, in the above-discussed semiconductor device 300, the gap for receiving the semiconductor element 302, the gap being formed between the first wiring board 301 and the second wiring board 305, is formed by making the diameter of the inside connection terminals 309 large. Accordingly, sizes in surface directions of the inside connection pads 321 and 338 and an arrangement pitch of the inside connection pads 321 and 338 are large. Because of this, the size in the surface direction of the semiconductor device 300 and the size in the thickness direction of the semiconductor device 300 are large.

Such problems are significant because the numbers of the inside connection pads 321 and 338 necessary for such semiconductor devices 300 are also becoming larger. In addition, such problems occur when a coreless board is used as the first wiring board 301 or the second wiring board 305.

### SUMMARY OF THE INVENTION

Accordingly, embodiments of the present invention may provide a novel and useful semiconductor device solving one or more of the problems discussed above.

More specifically, the embodiments of the present invention may provide a semiconductor device where a size in a thickness direction and a size of a surface direction of the semiconductor device can be made small.

One aspect of the embodiments of the present invention may be to provide a semiconductor device, including a first wiring board having a semiconductor element connection pad; a semiconductor element connected to the semiconductor element connection pad; and a second wiring board facing the semiconductor element and the first wiring board, the second wiring board being electrically connect to the first wiring board; wherein the semiconductor element includes an electrode configured to electrically connect a first surface of the semiconductor element and a second surface of the semiconductor element to each other; the first surface of the semiconductor element faces the first wiring board; the second surface of the semiconductor element faces the second wiring board; and the first wiring board and the second wiring board are electrically connected to each other via the electrode.

Another aspect of the embodiments of the present invention may be to a provide a semiconductor device including a first wiring board having a semiconductor element connection pad; a first semiconductor element electrically connected to the semiconductor element connection pad; and at least one second semiconductor element stacked on the first semiconductor element, the second semiconductor element being electrically connected to the first semiconductor element; and a second wiring board facing the first wiring board and the second semiconductor element, the second wiring board being electrically connected to the first wiring board; wherein a first piercing electrode is provided in the first semiconductor element so as to pierce the first semiconductor element, a second piercing electrode is provided in at least one second semiconductor element so as to pierce the second semiconductor element; and the first wiring board and the second wiring board are electrically connected to each other via the first piercing electrode and the second piercing electrode.

Other aspect of the embodiments of the present invention may be to a provide a semiconductor device, including a first wiring board having a semiconductor element connection pad; a first semiconductor element electrically connected to the semiconductor element connection pad; and at least one second semiconductor element stacked on the first semiconductor element, the second semiconductor element being electrically connected to the first semiconductor element; and a second wiring board facing the first wiring board and the second semiconductor element, the second wiring board being electrically connected to the first wiring board; wherein a first end surface electrode is provided on an end surface of the first semiconductor element, a second end surface electrode is provided on an end surface of the at least one second semiconductor element; and the first wiring board and the second wiring board are electrically connected to each other via the first end surface electrode and the second end surface electrode.

Additional objects and advantages of the embodiments will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention as claimed.

### BRIEF DESCRIPTION OF THE DRAWINGS

FIG. 1 is a cross-sectional view of a related art semiconductor device;

FIG. 2 is a cross-sectional view of a semiconductor device of a first embodiment of the present invention;

FIG. 3 is a cross-sectional view of a semiconductor device of a second embodiment of the present invention;

FIG. 4 is a cross-sectional view of a semiconductor device of a third embodiment of the present invention;

FIG. 5 is a cross-sectional view of a semiconductor device of a fourth embodiment of the present invention;

FIG. 6 is a cross-sectional view of a semiconductor device of a fifth embodiment of the present invention; and

FIG. 7 is a cross-sectional view of a semiconductor device of a sixth embodiment of the present invention.

### DETAILED DESCRIPTION OF THE PREFERRED EMBODIMENTS

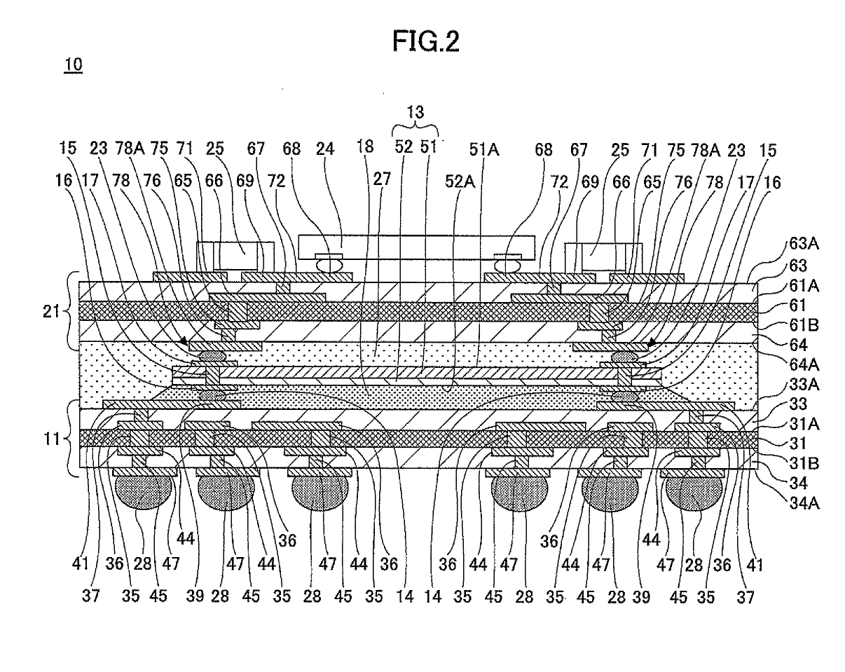

A description is given below, with reference to FIG. 2 through FIG. 7 of embodiments of the present invention.

### First Embodiment

FIG. 2 is a cross-sectional view of a semiconductor device of a first embodiment of the present invention.

Referring to FIG. 2, a semiconductor device 10 of the first embodiment of the present invention includes a first wiring board 11, a semiconductor element 13, inside connection terminals 14 and 23, piercing electrodes 15, pads 16 and 17, underfill resin 18, a second wiring board 21, electronic components 24 and 25, sealing resin 27, and outside connection terminals 28. The second wiring board 21 faces the first wiring board 11 and the semiconductor element 13. The semiconductor element 13 may be a WLP (Wafer Level Package).

The first wiring board 11 is a built-up board having a core. The first wiring board 11 includes a core board 31, insulation layers 33 and 34, piercing via-plugs 35, wirings 36, 41, and 44, via-plugs 37 and 45, semiconductor element connection pads 39, and outside connection pads 47.

The core board 31 is provided between the insulation layers 33 and 34. The core board 31 maybe, for example, a glass epoxy resin board where resin is impregnated in a glass fiber.

The insulation layer 33 is provided on the upper surface 31A of the core board 31. The insulation layer 33 covers parts of the wirings 36 and side surfaces of the via-plugs 37. For example, epoxy resin, polyimide resin, or the like may be used as a material of the insulation layer 33.

The insulation layer 34 is provided on the lower surface 31B of the core board 31 and covers parts of the wirings 44 and side surfaces of the via-plugs 45. For example, epoxy resin, polyimide resin, or the like may be used as a material of the insulation layer 34.

The piercing via-plugs 35 pierce the core board 31. Upper ends of the piercing via-plugs 35 are positioned in the substantially same plane as the upper surface 31A of the core board 31. Lower ends of the piercing via-plugs 35 are positioned in the substantially same plane as the lower surface 31B of the core board 31. For example, metal films such as copper (Cu) films may be used to form the piercing via-plugs 35.

The wirings 36 are provided on the upper surface 31A of the core board 31 and the upper ends of the piercing via-plugs 35. Because of this, the wirings 36 are electrically connected to the piercing via-plugs 35. For example, metal films such as copper (Cu) films may be used as the wirings 36.

The via-plugs 37 pierce parts of the insulation layer 33, the parts being provided on the wirings 36. Lower ends of the via-plugs 37 are electrically connected to the wirings 36. For example, metal films such as copper (Cu) films may be used to form the via-plugs 37.

The semiconductor element connection pads 39 are provided on the upper surface 33A of the insulation layer 33. The semiconductor element connection pads 39 are in a body with the wirings 41. The semiconductor element connection pads 39 are electrically connected to the via-plugs 37 via the wirings 41. The inside connection terminals 14 are provided on the semiconductor element connection pads 39. The semiconductor element connection pads 39 are electrically connected to the semiconductor element 13 via the inside connection terminals 14.

The wirings 41 are provided on the upper surface 33A of the insulation layer 33. The wirings 41 are formed in a body with the semiconductor element connection pads 39. The wirings 41 are connected to the upper ends of the via-plugs 37. The wirings 41 are electrically connected to the semiconductor element connection pads 39 and the via-plugs 37. For example, metal films such as copper (Cu) films may be used as the wirings 41 and the semiconductor element connection pads 39.

The wirings 44 are provided on the lower surface 31B of the core board 31 and the lower ends of the piercing via-plugs 35. Because of this, the wirings 44 are electrically connected to the piercing via-plugs 35. For example, metal films such as copper (Cu) films may be used as the wirings 44.

The via-plugs 45 pierce parts of the insulation layer 34, the parts being provided on the lower surfaces of the wirings 44. Upper ends of the via-plugs 45 are electrically connected to the wirings 44. For example, metal films such as copper (Cu) films may be used as the via-plugs 45.

The outside connection pads 47 are provided on a lower surface 34A of the insulation layer 34. The outside connection terminals 28 are provided on the outside connection pads 47. For example, metal films, such as copper (Cu) films may be used as the outside connection pads 47.

The semiconductor element 13 is flip-chip connected to the semiconductor element connection pads 39. The semiconductor element 13 includes a semiconductor substrate 51 and a semiconductor integrated circuit 52 formed on the semiconductor substrate 51. For example, a silicon substrate can be used as the semiconductor substrate 51. The semiconductor integrated circuit 52 is electrically connected to the piercing electrodes 15. The semiconductor integrated circuit 52 is electrically connected to the semiconductor element connection pads 39 via the piercing electrodes 15, the pads 16, and the inside connection terminals 14.

The inside connection terminals 14 are provided between the pads 16 and the semiconductor element connection pads 39 so as to come in contact with the pads 16 and the semiconductor element connection pads 39. The inside connection terminals 14 electrically connect the pads 16 to the semiconductor element 13 and the semiconductor element connection pads 39. For example, solder bumps, gold (Au) bumps, or the like may be used as the inside connection terminals 14. The heights of the inside connection terminals 14 provided between the semiconductor connection pads 39 and the pads 16 can be, for example, approximately 50 μm.

The piercing electrodes 15 are provided in the semiconductor element 13 so as to pierce the semiconductor element 13. The piercing electrodes 15 electrically connect a surface 52A (a first surface of the semiconductor element 13) of the semiconductor integrated circuit 52 facing the first wiring board 11 and a rear surface 51A (a second surface of the semiconductor element 13) of the semiconductor substrate 51 facing the second wiring board 21. The piercing electrodes 15 are electrically connected to the semiconductor integrated circuit 52. In addition, the piercing electrodes 15 are insulated from the semiconductor substrate 51. An end of each of the piercing electrodes 15 is positioned in the substantially same plane as the rear surface 51A of the semiconductor substrate 51. Another end of each of the piercing electrodes 15 is positioned in the substantially same plane as the surface 52A of the semiconductor integrated circuit 52. The piercing electrode 15 electrically connect the first wiring board 11 and the second wiring board 21 between a part of the first wiring board 11 facing the semiconductor element 13 and a part of the second wiring board 21 facing the semiconductor element 13.

Thus, the piercing electrodes 15 are provided in the semiconductor element 13 connected to the first wiring board 11 so as to pierce the semiconductor element 13 and be electrically connected to the semiconductor integrated circuit 52. As a result of this, it is possible to electrically connect the first wiring board 11 and the second wiring board 21 to each other by using the inside connection terminals 14 and 23 smaller than the inside connection terminals 309 of the related art semiconductor device 300 between the part of the first wiring board 11 facing the semiconductor element 13 and the part of the second wiring board 21 facing the semiconductor element 13.

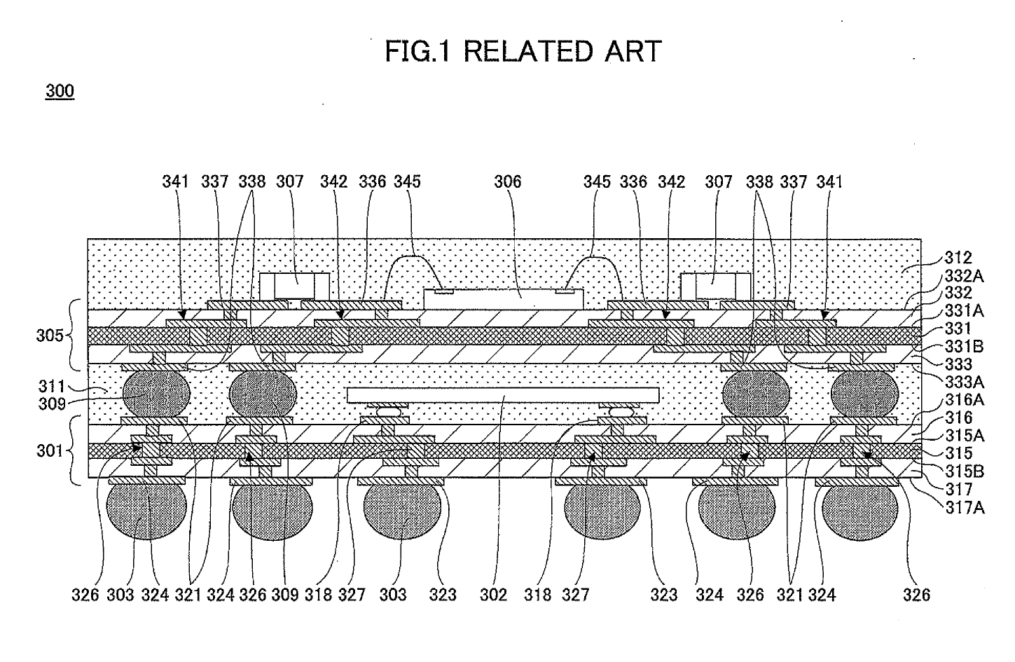

As a result of this, the inside connection pads 321 and 338 of the related art semiconductor device 300 (see FIG. 1) where the large inside connection terminals 309 for forming a gap between the first wiring board 301 and the second wiring board 305 for receiving the semiconductor element 302 are mounted, are not necessary in the semiconductor device 10. Accordingly, it is possible to make the sizes in the surface directions of the first wiring board 11 and the second wiring board 21 small so that the size in the surface direction of the semiconductor device 10 can be made small.

In addition, large inside connection terminals 309 provided in the related art semiconductor device 300 are not necessary. Hence, it is possible to make the size of the semiconductor device 10 in the thickness direction small.

The diameter of the piercing electrode 15 can be made small. In a case where the piercing electrode 15 has a circular-shaped plane configuration, the diameter of the piercing electrode 15 can be, for example, 0.1 mm. Thus, by making the diameter of the piercing electrode 15 small, it is possible to increase the number of the piercing electrodes 15 which can be formed on the semiconductor element 13. For example, metal films such as copper (Cu) films may be used as the piercing electrodes 15.

The pads 16 are provided on the lower ends of the piercing electrodes 15 and the surface 52A of the semiconductor integrated circuit 52. The pads 16 are connected to the inside connection terminals 14 provided on the semiconductor element connection pads 39. Because of this, the semiconductor element 13, more specifically the semiconductor integrated circuit 52, is electrically connected to the first wiring board 11. In a case where the diameter of the piercing electrode 15 is approximately 0.1 mm and the pad 16 has a circular-shaped plane configuration, the diameter of the pad 16 can be, for example, approximately 0.12 mm.

Thus, by providing the pads 16 connected to the lower ends of the piercing electrodes 15 on the surface 52A of the semiconductor integrated circuit 52, it is possible to improve an electrical connection reliability between the semiconductor element 13 and the first wiring board 11, as compared to a case where the inside connection terminals 14 are directly connected to the lower ends of the piercing electrodes 15.

The pads 17 are provided on the upper ends of the piercing electrodes 15 and the rear surface 51A of the semiconductor substrate 51. The pads 17 are connected to the inside connection terminals 23 connected to inside connection pads 78A. As a result of this, the semiconductor element 13 is electrically connected to the second wiring board 21. In a case where the diameter of the piercing electrode 15 is approximately 0.1 mm and the pad 17 has a circular-shaped plane configuration, the diameter of the pad 17 can be, for example, approximately 0.12 mm.

Thus, by providing the pads 17 connected to the upper ends of the piercing electrodes 15 on the rear surface 51A of the semiconductor substrate 51, it is possible to improve an electric connection reliability between the semiconductor element 13 and the second wiring board 21, as compared to a case where the inside connection terminals 23 are directly connected to the upper ends of the piercing electrodes 15.

The underfill resin 18 is supplied between the semiconductor element 13 and the first wiring board 11 facing the semiconductor element 13. Because of this, a gap between the semiconductor element 13 and the part of the first wiring board 11 facing the semiconductor element 13, the inside connection terminals 14, the pads 16, and the semiconductor element connection pads 39 are sealed by the underfill resin 18.

The second wiring board 21 is a built-up board having a core. The second wiring board 21 includes a core board 61, insulation layers 63 and 64, piercing via-plugs 65, wirings 66, 72, and 75, via-plugs 67 and 76, electric component connection pads 68, 69, and 71, and wiring patterns 78.

The core board 61 is provided between the insulation layers 63 and 64. The core board 61 may be, for example, a glass epoxy resin board where resin is impregnated in a glass fiber.

The insulation layer 63 is provided on an upper surface 61A of the core board 61. The insulation layer 63 covers parts of the wirings 66 and side surfaces of the via-plugs 67. For example, epoxy resin, polyimide resin, or the like may be used as a material of the insulation layer 63.

The insulation layer 64 is provided on a lower surface 61B of the core board 61 and covers parts of the wirings 75 and side surfaces of the via-plugs 76. For example, epoxy resin, polyimide resin, or the like may be used as a material of the insulation layer 64.

The piercing via-plugs 65 pierce the core board 61. Upper ends of the piercing via-plugs 65 are positioned in the substantially same plane as the upper surface 61A of the core board 61. Lower ends of the piercing via-plugs 65 are positioned in the substantially same plane as the lower surface 61B of the core board 61. For example, metal films such as copper (Cu) films may be used as the piercing via-plugs 65.

The wirings 66 are provided on the upper surface 61A of the core board 61 and the upper ends of the piercing via-plugs 65. Because of this, the wirings 66 are electrically connected to the piercing via-plugs 65. For example, metal films such as copper (Cu) films may be used as the wirings 66.

The via-plugs 67 pierce parts of the insulation layer 63, the parts being provided on the wirings 66. Lower ends of the via-plugs 67 are electrically connected to the wirings 66. For example, metal films such as copper (Cu) films may be used to form the via-plugs 67.

The electronic component mounting pads 68 are provided on an upper surface 63A of the insulation layer 63. The electronic component mounting pads 68 are in a body with the wirings 72. The electronic component mounting pads 68 are electrically connected to the via-plugs 67. The electronic component 24 is provided on the electronic component mounting pads 68.

The electronic component mounting pads 69 are provided on the upper surface 63A of the insulation layer 63. The electronic component mounting pads 69 are in a body with the wirings 72. The electronic component mounting pads 69 are electrically connected to the via-plugs 67 and the electronic component mounting pads 68. The electronic components 25 are provided on the electronic component mounting pads 69.

The electronic component mounting pads 71 are provided on the upper surface 63A of the insulation layer 63. The electronic components 25 are provided on the electronic component mounting pads 71. For example, metal films such as copper (Cu) films may be used as the electronic component mounting pads 71.

The wirings 72 are provided on the upper surface 63A of the core board 63. End parts of the wirings 72 are formed in a body with the electronic component mounting pads 68. Other end parts of the wirings 72 are formed in a body with the electronic component mounting pads 69. The wirings 72 electrically connect the electronic component mounting pads 68 and the electronic component mounting pads 69 to each other. For example, metal films such as copper (Cu) films may be used as the wirings 72 the electronic component mounting pads 68, and the electronic component mounting pads 69.

The wirings 75 are provided on the lower surface 61B of the core board 61 and the lower ends of the piercing via-plugs 65. Because of this, the wirings 75 are electrically connected to the piercing via-plugs 65. For example, metal films such as copper (Cu) films may be used as the wirings 75.

The via-plugs 76 pierce parts of the insulation layer 64, the parts being provided on the lower surfaces of the wirings 75. Upper ends of the via-plugs 76 are electrically connected to the wirings 75. For example, metal films such as copper (Cu) films may be used to form the via-plugs 76.

The wiring patterns 78 are provided on the lower ends of the via-plugs 76 and a lower surface 64A of the insulation layer 64. The wiring patterns 78 are electrically connected to the via-plugs 76. The wiring patterns 78 include the inside connection pads 78A. The inside connection pads 78A are connected to the inside connection terminals 23 provided on the pads 17. Because of this, the second wiring board 21 is electrically connected to the first wiring board 11 and the semiconductor element 13 via the piercing electrodes 15. For example, metal films such as copper (Cu) films may be used as the wiring patterns 78.

The inside connection terminals 23 are provided between the pads 17 and the inside connection pads 78A so as to come in contact with the pads 17 and the inside connection pads 78A. The inside connection terminals 23 electrically connect the pads 17 to the semiconductor element 13 and the inside connection pads 78A. For example, solder bumps, gold (Au) bumps, or the like may be used as the inside connection terminals 23. The heights of the inside connection terminals 23 provided between the inside connection pads 78A and the pads 17 can be, for example, approximately 50 μm.

Thus, the inside connection terminals 23 configured to come in contact with the pads 17 and the inside connection pads 78A are provided between the pads 17 and the inside connection pads 78A. Via the piercing electrodes 15 provided in the semiconductor element 13, the second wiring board 21, the semiconductor element 13, and the first wiring board 11 are electrically connected to each other. Compared to the case where the first wiring board 11 and the second wiring board 21 are electrically connected to each other by the large inside connection terminals 309 (see FIG. 1), it is possible to make the size in the thickness direction of the semiconductor device 10 small.

The electronic component 24 is connected to (mounted on) the electronic component connection pads 68. Because of this, the electronic component 24 is electrically connected to the second wiring board 21. For example, a semiconductor chip can be used as the electronic component 24.

The electronic components 25 are connected to (mounted on) the electronic component connection pads 69 and 71. Because of this, the electronic components 25 are electrically connected to the second wiring board 21 and the electronic component 24. For example, chip resistors, chip inductors, chip capacitors, and other components can be used as the electronic components 25.

The sealing resin 27 is provided so as to fill the gap between the first wiring board 11 and the second wiring board 21. The sealing resin 27 seals the semiconductor element 13, the inside connection terminals 23, and the underfill resin 18.

Thus, by providing the sealing resin 27 to fill the gap between the first wiring board 11 and the second wiring board 21, it is possible to prevent damage to the semiconductor element 13 and improve the electrical reliability between the piercing electrode 15 and the second wiring board 21 (more specifically between the pad 17 and the inside connection pad 78A). It should be noted that, however, it is not always necessary to provide the sealing resin 27.

The outside connection terminals 28 are provided on the lower surfaces of the outside connection pads 47. The outside connection terminals 28 are connected to pads (not shown in FIG. 2) provided on a mounting board such as a motherboard.

According to the semiconductor device of the first embodiment of the present invention, the piercing electrodes 15 configured to pierce the semiconductor element 13 and to be electrically connected to the semiconductor integrated circuit 52 are provided in the semiconductor element 13 electrically connected to the first wiring board 11. The first wiring board 11 and the second wiring board 21 are electrically connected to each other via the piercing electrodes 15. Therefore, it is not necessary to provide the inside connection pads 321 and 338 where large inside connection terminals 309 are provided, as is required in the related art semiconductor device 300 (see FIG. 1). Hence, it is possible to make the size of the semiconductor device 10 in the surface direction small.

In addition, because it is not necessary to provide the large inside connection terminals 309 required in the related art semiconductor device 300, it is possible to make the size of the semiconductor device 10 in the thickness direction small.

The first embodiment of the present invention can be applied to a semiconductor device called Package-On-Package (POP) not having the sealing resin 27 provided between the first wiring board 11 and the second wiring board 21. In addition, sealing resin configured to seal the electronic components 24 and 25 may be provided on the upper surface of the second wiring board 21.

### Second Embodiment

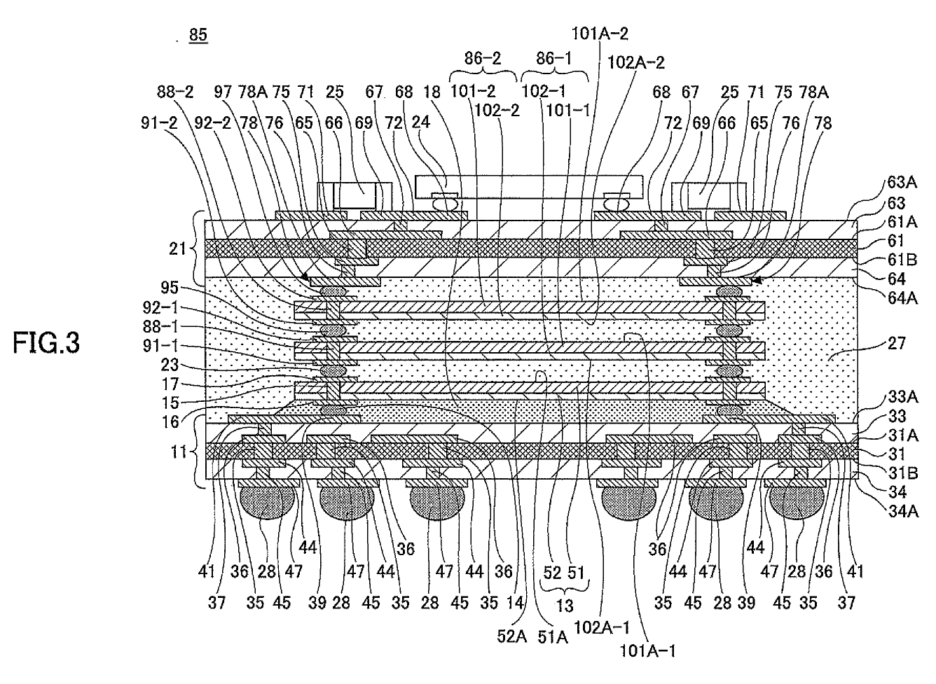

FIG. 3 is a cross-sectional view of a semiconductor device of a second embodiment of the present invention. In FIG. 3, parts that are the same as the parts of the semiconductor device 10 shown in FIG. 2 are given the same reference numerals, and explanation thereof is omitted.

Referring to FIG. 3, a semiconductor device 85 of the second embodiment of the present invention has the same structure as that of the semiconductor device 10 of the first embodiment of the present invention except the semiconductor elements 86-1 and 86-2 (second semiconductor elements), piercing electrodes 88-1 and 88-2, pads 91-1, 91-2, 92-1, and 92-2, and inside connection terminals 95 and 97 are provided in the semiconductor device 85 of the second embodiment of the present invention.

The semiconductor element 86-1 is stacked on the semiconductor element (first semiconductor element) 13. The semiconductor element 86-1 includes a semiconductor substrate 101-1 and a semiconductor integrated circuit 102-1 formed on the semiconductor substrate 101-1. For example, a silicon substrate can be used as the semiconductor substrate 101-1. The semiconductor integrated circuit 102-1 is electrically connected to the piercing electrodes 88-1 provided in the semiconductor element 86-1. The semiconductor element 86-1 is electrically connected to the first wiring board 11 and the semiconductor element 13 via the piercing electrode 88-1 provided in the semiconductor element 86-1.

The semiconductor element 86-2 is stacked on the semiconductor element 86-1. The semiconductor element 86-2 includes a semiconductor substrate 101-2 and a semiconductor integrated circuit 102-2 formed on the semiconductor substrate 101-2. For example, a silicon substrate can be used as the semiconductor substrate 101-2. The semiconductor integrated circuit 102-2 is electrically connected to the piercing electrode 88-2 provided in the semiconductor element 86-2. The semiconductor element 86-2 is electrically connected to the first wiring board 11, the semiconductor elements 13 and 86-1, and the second wiring board 21 via the piercing electrodes 88-2 provided in the semiconductor element 86-2.

The semiconductor elements 86-1 and 86-2 stacked on the semiconductor element 13 are sealed by the sealing resin 27.

The piercing via-plugs (second piercing electrodes) 88-1 are provided in the semiconductor element 86-1 so as to pierce the semiconductor element 86-1. The piercing electrodes 88-1 are electrically connected to the semiconductor integrated circuit 102-1 and are insulated from the semiconductor substrate 101-1. End surfaces of the piercing via-plugs 88-1 are positioned in the substantially same plane as a rear surface 101A-1 of the semiconductor substrate 101-1. Other ends of the piercing via-plugs 88-1 are positioned in the substantially same plane as a surface 102A-1 of the semiconductor integrated circuit 102-1. The piercing electrodes 88-1 electrically connect the semiconductor element 13 and the semiconductor element 86-2 to each other. In a case where the piercing electrode 88-1 has a circular-shaped plane configuration, the diameter of the piercing electrode 88-1 can be, for example, approximately 0.1 mm.

The piercing via-plugs (second piercing electrodes) 88-2 are provided in the semiconductor element 86-2 so as to pierce the semiconductor element 86-2. The piercing electrodes 88-2 are electrically connected to the semiconductor integrated circuit 102-2 and are insulated from the semiconductor substrate 101-2. End surfaces of the piercing via-plugs 88-2 are positioned in the substantially same plane as a rear surface 101A-2 of the semiconductor substrate 101-2. Other ends of the piercing via-plugs 88-2 are positioned in the substantially same plane as a surface 102A-2 of the semiconductor integrated circuit 102-2. The piercing electrodes 88-2 electrically connect the semiconductor element 86-1 and the second wiring board 21 to each other. In a case where the piercing electrode 88-2 has a circular-shaped plane configuration, the diameter of the piercing electrode 88-2 can be, for example, approximately 0.1 mm. For example, metal films such as copper (Cu) films may be used to form the piercing electrodes 88-1 and 88-2.

The pads 91-1 are provided on the lower ends of the piercing electrodes 88-1 and the surface 102A-1 of the semiconductor integrated circuit 102-1. The pads 91-1 are connected to the inside connection terminals 23 provided on the semiconductor element connection pads 17. Because of this, the semiconductor element 86-1 is electrically connected to the first wiring board 11 and the semiconductor element 13 via the piercing electrodes 15 and 88-1. In a case where the diameter of the piercing electrode 88-1 is approximately 0.1 mm and the pad 91-1 has a circular-shaped plane configuration, the diameter of the pad 91-1 can be, for example, approximately 0.12 mm.

The pads 91-2 are provided on the lower ends of the piercing electrodes 88-2 and the surface 102A-2 of the semiconductor integrated circuit 102-2. The pads 91-2 are connected to the inside connection terminals 95 provided on the pads 92-1 provided on the upper ends of the piercing electrodes 88-1. Because of this, the semiconductor element 86-2 is electrically connected to the semiconductor element 86-1 via the piercing electrodes 88-2. In a case where the diameter of the piercing electrode 88-2 is approximately 0.1 mm and the pad 91-2 has a circular-shaped plane configuration, the diameter of the pad 91-2 can be, for example, approximately 0.12 mm.

The pads 92-1 are provided on the upper ends of the piercing electrodes 88-1 and the rear surface 101A-1 of the semiconductor substrate 101-1. The pads 92-1 are connected to the pads 91-2 via the inside connection terminals 95. In a case where the diameter of the piercing electrode 88-1 is approximately 0.1 mm and the pad 92-1 has a circular-shaped plane configuration, the diameter of the pad 92-1 can be, for example, approximately 0.12 mm.

The pads 92-2 are provided on the upper ends of the piercing electrodes 88-2 and the surface 101A-2 of the semiconductor substrate 101-2. The pads 92-2 are electrically connected to the inside connection pads 78A provided on the second wiring board 21. In a case where the diameter of the piercing electrode 88-2 is approximately 0.1 mm and the pad 92-2 has a circular-shaped plane configuration, the diameter of the pad 92-2 can be, for example, approximately 0.12 mm.

The inside connection terminals 95 are provided between the pads 92-1 and the pads 91-2 so as to come in contact with the pads 92-1 and the pads 91-2. The inside connection terminals 95 electrically connect the pads 92-1 and the pads 91-2 to each other. For example, solder bumps, gold (Au) bumps, or the like may be used as the inside connection terminals 95. The heights of the inside connection terminals 95 provided between the pads 92-1 and the pads 91-2 can be, for example, approximately 50 μm.

The inside connection terminals 97 are provided between the pads 92-2 and the inside connection pads 78A so as to come in contact with the pads 92-2 and the inside connection pads 78A. The inside connection terminals 97 electrically connect the pads 92-2 and the inside connection pads 78A to each other. For example, solder bumps, gold (Au) bumps, or the like may be used as the inside connection terminals 97. The heights of the inside connection terminals 97 provided between the pads 92-2 and the inside connection pads 78A can be, for example, approximately 50 μm.

According to the second embodiment of the present invention, the piecing electrodes (first piercing electrodes) 15 are provided in the semiconductor element (first semiconductor element) 13 provided on and electrically connected to the first wiring board 11. The piercing electrode 15 pierces the semiconductor element 13. The piercing electrodes (second piercing electrodes) 88-1 and 88-2 pierces the semiconductor element 86-1 and the semiconductor element (second semiconductor element) 86-2, respectively, stacked on the semiconductor element 13. The first wiring board 11 and the second wiring board 21 facing the first wiring board 11 and the semiconductor element 86-2 are electrically connected to each other via the piercing electrodes 15, 88-1 and 88-2.

Therefore, it is not necessary to provide the inside connection pads 321 and 338 with the large inside connection terminals 309 required in the related art semiconductor device 300 (see FIG. 1). Hence, it is possible to make the size of the semiconductor device 85 in the surface direction small.

In addition, because it is not necessary to provide the large inside connection terminal 309 required in the related art semiconductor device 300, it is possible to make the size of the semiconductor device 85 in the thickness direction small.

In the second embodiment of the present invention, two semiconductor elements (more specifically, semiconductor elements 86-1 and 86-2) having piercing electrodes are stacked on the semiconductor element 13 connected to the semiconductor element connection pads 39 of the first wiring board 11. However, the present invention is not limited to this. The number of the semiconductor elements stacked on the semiconductor element 13 and having the piercing electrodes may be one or greater than three.

### Third Embodiment

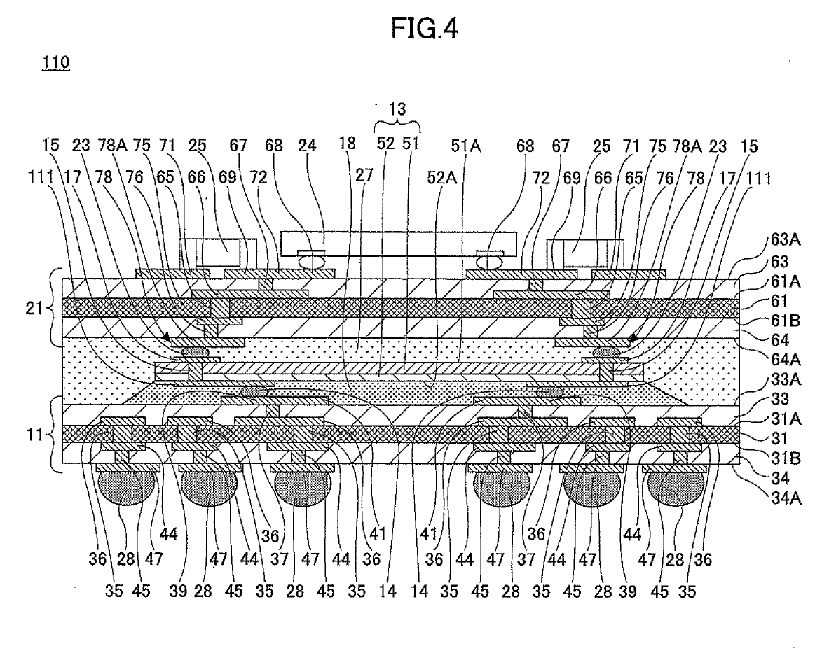

FIG. 4 is a cross-sectional view of a semiconductor device of a third embodiment of the present invention. In FIG. 4, parts that are the same as the parts of the semiconductor device 10 shown in FIG. 2 are given the same reference numerals, and explanation thereof is omitted.

Referring to FIG. 4, a semiconductor device 110 of the third embodiment of the present invention has the same structure as that of the semiconductor device 10 of the first embodiment of the present invention except wiring patterns 111 are provided instead of the pads 16 provided in the semiconductor device 10.

The wiring patterns 111 are provided on the lower ends of the piercing electrodes 15 and the surface 52A of the semiconductor integrated circuit 52. The wiring patterns 111 extend from the lower ends of the piercing electrodes 15 to parts of the surface 52A of the semiconductor integrated circuit 52 facing the semiconductor element connection pads 39. The wiring patterns 111 facing the semiconductor element connection pads 39 are connected to the inside connection terminals 14 provided on the semiconductor element connection pads 39. Because of this, the semiconductor element 13 is electrically connected to the first wiring board 11 via the inside connection terminals 14 and the wiring patterns 111.

According to the semiconductor device 110 of the third embodiment of the present invention, the wiring patterns 111 are provided so as to be connected to the lower ends of the piercing electrodes 15 and electrically connected to the semiconductor element connection pads 39 provided on the first wiring board 11 via the inside connection terminals 14. Accordingly, without depending on the positions of the semiconductor element connection pads 39 provided on the first wiring board 11, it is possible to electrically connect the piercing electrodes 15 and the semiconductor element connection pads 39 to each other.

In the third embodiment of the present invention, the wiring patterns 111 connected to the lower ends of the piercing electrodes 15 are provided on the surface of the semiconductor element 13 facing the first wiring board 11, namely the surface 52A of the semiconductor integrated circuit 52. However, the present invention is not limited to this. For example, instead of the pads 17, wiring patterns connected to the inside connection terminals 23 may be provided on the surface of the semiconductor element 13 facing the second wiring board 21, namely the surface 51A of the semiconductor integrated circuit 51. In addition, wiring patterns electrically connected to the piercing electrodes 15 may be provided on both surfaces of the semiconductor element 13.

### Fourth Embodiment

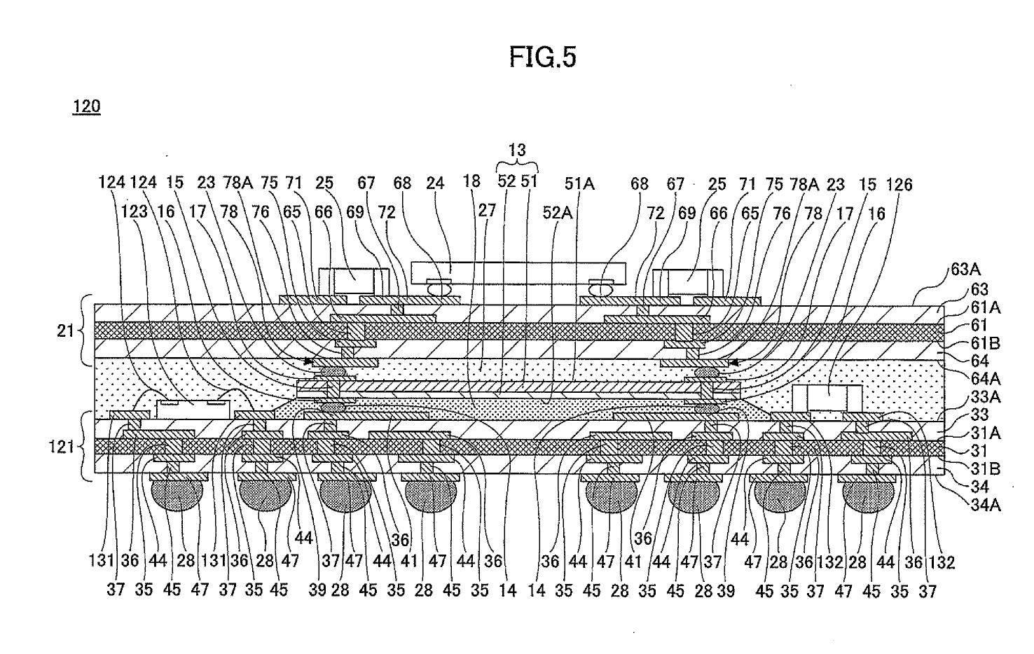

FIG. 5 is a cross-sectional view of a semiconductor device of a fourth embodiment of the present invention. In FIG. 5, parts that are the same as the parts of the semiconductor device 10 shown in FIG. 2 are given the same reference numerals, and explanation thereof is omitted.

As shown in FIG. 5, a semiconductor device 120 of the fourth embodiment of the present invention has the same structure as the semiconductor device 10 of the first embodiment of the present invention except the following. That is, in the semiconductor device 120, a first wiring board 121 instead of the first wiring board 11 is provided and a semiconductor element 123 and an electronic component 126 are provided.

The first wiring board 121 has the same structure as that of the first wiring board 11 except semiconductor element connection pads 131 and electronic component connection pads 132 are provided on the upper surface 33A of the insulation layer 33 and connected to the upper ends of the via-plugs 37. The semiconductor element connection pads 131 are connected to the metal wires 124. For example, metal films such as copper (Cu) films may be used as the semiconductor element connection pads 131 and the electronic component connection pads 132.

The semiconductor element 123 is adhered on the upper surface 33A of the insulation layer 33. The semiconductor element 123 is electrically connected (wire-bonding connected) to the semiconductor element connection pads 131 via the metal wires 124. Because of this, the semiconductor element 123 is electrically connected to the first wiring board 121. The surface of the semiconductor element 123 where the metal wires 124 are connected is lower than the rear surface 51A of the semiconductor substrate 51 of the semiconductor element 13 connected to the first wiring board 121.

The electronic component 126 is connected to the electronic component connection pads 132. Because of this, the electronic component 126 is electrically connected to the first wiring board 121. The upper surface of the electronic component 126 is lower than the rear surface 51A of the semiconductor substrate 51 of the semiconductor element 13 connected to the first wiring board 121.

Thus, in the case where plural semiconductor elements 13 and 123 and the electronic component 126 are connected to the first wiring board 121, the piercing electrodes 15 are provided in the semiconductor element or the electronic component (the semiconductor element 13 in this case) having the greatest height of the surface facing the second wiring board 21 so that the first wiring board 121 and the second wiring board 21 are electrically connected to each other via the piercing electrodes 15.

The semiconductor element 123, the metal wires 124 and the electronic component 126 are sealed by the sealing resin 27 provided between the first wiring board 121 and the second wiring board 21.

According to the fourth embodiment of the present invention, in the case where plural semiconductor elements 13 and 123 and the electronic component 126 are connected to (mounted on) the first wiring board 121, the piercing electrodes 15 are provided in the semiconductor element or the electronic component (the semiconductor element 13 in this case) having the greatest height of the surfaces facing the second wiring board 21 so that the first wiring board 121 and the second wiring board 21 are electrically connected to each other via the piercing electrodes 15 and the sizes in the thickness directions and the surface directions of the semiconductor device 120 can be made small.

In the fourth embodiment of the present invention, the semiconductor element 123 is wire-bonding connected to the first wiring board 121. However, the present invention is not limited to this. The semiconductor element 123 may be flip-chip connected to the first wiring board 121.

### Fifth Embodiment

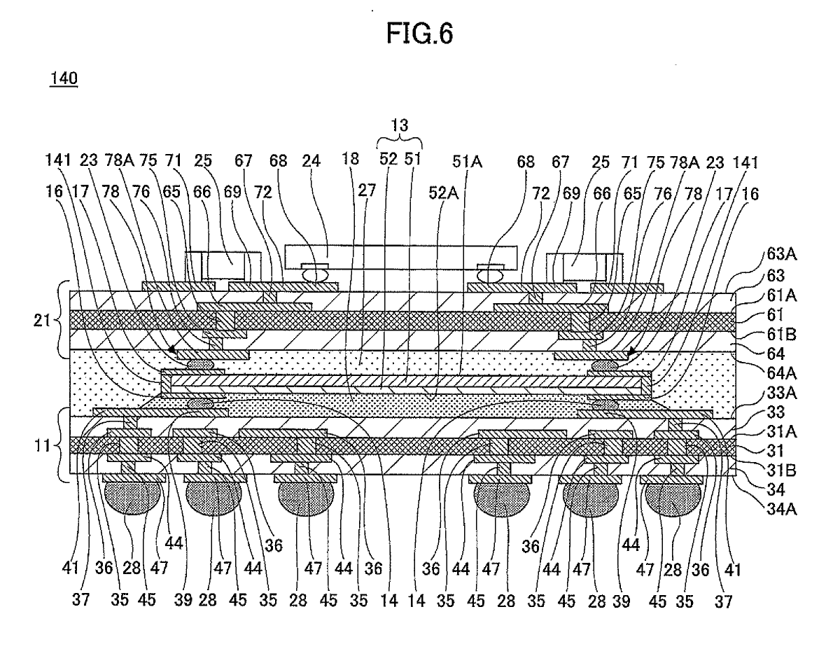

FIG. 6 is a cross-sectional view of a semiconductor device of a fifth embodiment of the present invention. In FIG. 6, parts that are the same as the parts of the semiconductor device 10 shown in FIG. 2 are given the same reference numerals, and explanation thereof is omitted.

Referring to FIG. 6, a semiconductor device 140 of the fifth embodiment of the present invention has the same structure as that of the semiconductor device 10 except having end surface electrodes 141 provided on end surfaces of the semiconductor element 13, instead of the piercing electrodes 15 provided in the semiconductor device 10 of the first embodiment of the present invention.

The end surface electrodes 141 electrically connect the surface 52A of the semiconductor integrated circuit 52 facing the first wiring board 11, namely the first surface of the semiconductor element 13, and the rear surface 51A of the semiconductor substrate 51 facing the second wiring board 21, namely the second surface of the semiconductor element, to each other. The end surface electrodes 141 are electrically connected to the semiconductor integrated circuit 52. The end surface electrodes 141 are insulated from the semiconductor substrate 51. Upper ends of the end surface electrodes 141 are connected to the pads 17 electrically connected to the second wiring board 21. Lower ends of the surface electrodes 141 are connected to the pads 16 electrically connected to the first wiring board 11. Because of this, the end surface electrodes 141 electrically connect the first wiring board 11 and the second wiring board 21.

Thus, since the end surface electrodes 141 are provided on the end surfaces of the semiconductor element 13 connected to the first wiring board 11, between the part of the first wiring board 11 facing the semiconductor element 13 and the part of the second wiring board 21 facing the semiconductor element 13, it is possible to electrically connect the first wiring board 11 and the second wiring board 21 by using the inside connection terminals 14 and 23, which are smaller than the inside connection terminals 309 provided in the related art semiconductor device 300 (see FIG. 1).

Therefore, it is not necessary to provide the inside connection pads 321 and 338 and the large inside connection terminals 309, for forming the gap where the semiconductor element 302 is received between the first wiring board 301 and the second wiring board 305, required in the related art semiconductor device 300 (see FIG. 1). Hence, it is possible to make the size of the semiconductor device 140 in the surface direction small.

In addition, because it is not necessary to provide the large inside connection terminals 309 required in the related art semiconductor device 300, it is possible to make the size of the semiconductor device 140 in the thickness direction small.

By making the size (area) of the end surface electrode 141 small, it is possible to increase the number of the end surface electrodes 141 which can be formed in the semiconductor element 13. For example, metal films such as copper (Cu) films may be used as the end surface electrodes 141.

According to the fifth embodiment of the present invention, the end surface electrodes 141 are provided on the end surfaces of the semiconductor element 13 connected to the semiconductor element connection pads 39 provided on the first wiring board 11. The first wiring board 11 and the second wiring board 21 are electrically connected to each other via the end surface electrodes 141. Therefore, it is not necessary to provide the inside connection pads 321 and 338 where large inside connection terminals 309 are provided, which are required in the related art semiconductor device 300 (see FIG. 1). Hence, it is possible to make the size of the semiconductor device 140 in the surface direction small.

In addition, because it is not necessary to provide the large inside connection terminals 309 required in the related art semiconductor device 300, it is possible to make the size of the semiconductor device 140 in the thickness direction small.

The fifth embodiment of the present invention can be applied to a semiconductor device called Package-On-Package (POP) not having the sealing resin 27 provided between the first wiring board 11 and the second wiring board 21. In addition, sealing resin configured to seal the electronic components 24 and 25 may be provided on the upper surface of the second wiring board 21.

### Sixth Embodiment

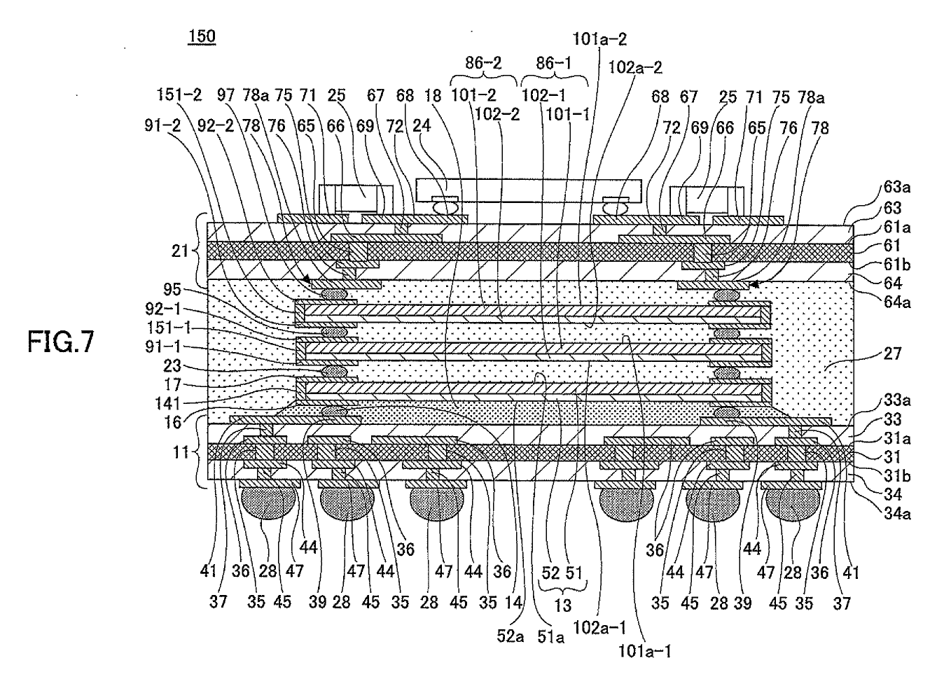

FIG. 7 is a cross-sectional view of a semiconductor device of a sixth embodiment of the present invention. In FIG. 7, parts that are the same as the parts of the semiconductor device 85 of the second embodiment of the present invention are given the same reference numerals, and explanation thereof is omitted.

Referring to FIG. 7, a semiconductor device 150 of the sixth embodiment of the present invention has the same structure as the semiconductor device 85 of the second embodiment of the present invention except end surface electrodes 151-1 and 151-2 are provided instead of the piercing electrodes 88-1 and 88-2 provided in the semiconductor device 85.

The end surface electrodes 151-1 are provided on the end surfaces of the semiconductor element 86-1. The end surface electrodes 1511 are electrically connected to a surface 102a-1 of the semiconductor integrated circuit 102-1 and a rear surface 101a-i of the semiconductor substrate 101-1. The end surface electrodes 151-1 are electrically connected to the semiconductor integrated circuit 102-1 and insulated from the semiconductor substrate 101-1. The upper end of the end surface electrode 151-1 are connected to the pads 92-1 connected to the inside connection terminals 95. The lower end of the end surface electrodes 151-1 are connected to the pads 911 connected to the inside connection terminals 23. Because of this, the end surface electrodes 151-1 electrically connect the semiconductor element 13 and the semiconductor element 86-2 to each other.

The end surface electrodes 151-2 are provided on the end surfaces of the semiconductor elements 86-2. The end surface electrodes 151-2 are electrically connected to a surface 102a-2 of the semiconductor integrated circuit 102-2 and a rear surface 101a-2 of the semiconductor substrate 101-2. The end surface electrodes 151-2 are electrically connected to the semiconductor integrated circuit 102-2 and insulated from the semiconductor substrate 101-2. The upper end of the end surface electrode 151-2 are connected to the pads 92-2 connected to the inside connection terminals 97. The lower ends of the end surface electrodes 151-2 are connected to the pads 91-2 connected to the inside connection terminals 95. Because of this, the end surface electrodes 151-2 electrically connect the second wiring board 21 and the semiconductor element 86-1 to each other.

According to the sixth embodiment of the present invention, the end surface electrodes (first end surface electrode) 141 are provided on the end surfaces of the semiconductor element (first semiconductor element) 13 provided on and electrically connected to the first wiring board 11. The end surface electrodes (second end surface electrodes) 151-1 and 151-2 are provided on the end surfaces of the semiconductor elements (second semiconductor elements) 86-1 and 86-2, respectively, stacked on the semiconductor element 13. The first wiring board 11 and the second wiring board 21 facing the first wiring board 11 and the semiconductor element 86-2 are electrically connected to each other via the end surface electrodes 141, 151-1 and 151-2. Therefore, it is not necessary to provide the inside connection pads 321 and 338 where large inside connection terminals 309 are provided as required in the related art semiconductor device 300 (see FIG. 1). Hence, it is possible to make the size of the semiconductor device 150 in the surface direction small.

In addition, because it is not necessary to provide the large inside connection terminal 309 required in the related art semiconductor device 300, it is possible to make the size of the semiconductor device 150 in the thickness direction small.

In the sixth embodiment of the present invention, two semiconductor elements (more specifically, semiconductor elements 86-1 and 86-2) having the end surface electrodes 141, 151-1, and 151-2 are stacked on the semiconductor element 13 connected to the semiconductor element connection pads 39 of the first wiring board 11. However, the present invention is not limited to this. The number of the semiconductor elements stacked on the semiconductor element 13 and having the end surface electrodes may be one or greater than three.

According to the above-discussed embodiments, it is possible to provide a semiconductor device, including a first wiring board having a semiconductor element connection pad; a semiconductor element connected to the semiconductor element connection pad; and a second wiring board facing the semiconductor element and the first wiring board, the second wiring board being electrically connect to the first wiring board; wherein the semiconductor element includes an electrode configured to electrically connect a first surface of the semiconductor element and a second surface of the semiconductor element to each other; the first surface of the semiconductor element faces the first wiring board; the second surface of the semiconductor element faces the second wiring board; and the first wiring board and the second wiring board are electrically connected to each other via the electrode.

According to the above-mentioned semiconductor device, the electrodes configured to electrically connect the first surface of the semiconductor element facing the first wiring board and the second surface of the semiconductor element facing the second wiring board to each other are provided on the semiconductor element connected to the semiconductor element connection pad provided on the first wiring board. The first wiring board and the second wiring board are electrically connected to each other via the electrodes. Therefore, it is not necessary to provide the inside connection pads where large inside connection terminals are provided as required in the related art semiconductor device. Hence, it is possible to make the size of the semiconductor device in the surface direction small.

In addition, because it is not necessary to provide the inside connection pads, where large inside connection terminals are provided, required in the related art semiconductor device, it is possible to make the size of the semiconductor device in the thickness direction small.

According to the above-discussed embodiments, it is also possible to provide a semiconductor device, including: a first wiring board having a semiconductor element connection pad; a first semiconductor element electrically connected to the semiconductor element connection pad; and at least one second semiconductor element stacked on the first semiconductor element, the second semiconductor element being electrically connected to the first semiconductor element; and a second wiring board facing the first wiring board and the second semiconductor element, the second wiring board being electrically connected to the first wiring board; wherein a first piercing electrode is provided in the first semiconductor element so as to pierce the first semiconductor element, a second piercing electrode is provided in at least one second semiconductor element so as to pierce the second semiconductor element; and the first wiring board and the second wiring board are electrically connected to each other via the first piercing electrode and the second piercing electrode.

According to the above-mentioned semiconductor device, the first piercing electrode is provided in the first semiconductor element so as to pierce the first semiconductor element. The second piercing electrode is provided in at least one second semiconductor element stacked on the first semiconductor element so as to pierce the second semiconductor element. The first wiring board and the second wiring board are electrically connected to each other via the first piercing electrode and the second piercing electrode. Therefore, it is not necessary to provide the inside connection pad where the large inside connection terminal is provided, as required in the related art semiconductor device. Hence, it is possible to make the size of the semiconductor device in the surface direction small.

In addition, because it is not necessary to provide the inside connection pad, where the large inside connection terminal is provided, as required in the related art semiconductor device, it is possible to make the size of the semiconductor device in the thickness direction small.

According to the above-discussed embodiments, it is also possible to provide a semiconductor device, including a first wiring board having a semiconductor element connection pad; a first semiconductor element electrically connected to the semiconductor element connection pad; and at least one second semiconductor element stacked on the first semiconductor element, the second semiconductor element being electrically connected to the first semiconductor element; and a second wiring board facing the first wiring board and the second semiconductor element, the second wiring board being electrically connected to the first wiring board; wherein a first end surface electrode is provided on an end surface of the first semiconductor element, a second end surface electrode is provided on an end surface of the at least one second semiconductor element; and the first wiring board and the second wiring board are electrically connected to each other via the first end surface electrode and the second end surface electrode.

According to the above-mentioned semiconductor device, the first end surface electrode is provided on the end surface of the first semiconductor element. The second end surface electrode is provided on the end surface of at least one second semiconductor element stacked on the first semiconductor element. The first wiring board and the second wiring board are electrically connected to each other via the first end surface electrode and the second end surface electrode. Therefore, it is not necessary to provide the inside connection pad, where the large inside connection terminal is provided, as required in the related art semiconductor device. Hence, it is possible to make the size of the semiconductor device in the surface direction small.

In addition, because it is not necessary to provide the inside connection pad, where the large inside connection terminal is provided, as required in the related art semiconductor device, it is possible to make the size of the semiconductor device in the thickness direction small.

Thus, according to the embodiments of the present invention, it is possible to make the sizes in the thickness direction and the surface direction of the semiconductor device small.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiment of the present invention has been described in detail, it should be understood that the various changes, substitutions, and alterations could be made hereto without departing from the spirit and scope of the invention.

For example, in the semiconductor element 13 of the semiconductor devices 10, 85, 110, 120, 140, and 150 of the first through sixth embodiments of the present invention, the semiconductor substrate 51 faces the second wiring board 21. However, the present invention is not limited to this. The semiconductor element may be reversed upside down so that the semiconductor integrated circuit 52 may face the second wiring board 21.

In addition, the via-plugs 35, 37, 45, 65, 67, and 76 and the electrodes 15, 88-1, 88-2, 141, 151-1, and 151-2 may be formed by a plating process such as a Cu plating process or a metal plating process.

This patent application is based on Japanese Priority Patent Application No. 2007-316698 filed on Dec. 7, 2007, the entire contents of which are hereby incorporated herein by reference.

What is claimed is:

1. A semiconductor device, comprising:
a first wiring board having a semiconductor element connection pad;
a semiconductor element connected to the semiconductor element connection pad; and
a second wiring board facing the semiconductor element and the first wiring board, the second wiring board being electrically connect to the first wiring board;
wherein the semiconductor element includes an electrode configured to electrically connect a first surface of the semiconductor element and a second surface of the semiconductor element to each other;
the first surface of the semiconductor element faces the first wiring board;
the second surface of the semiconductor element faces the second wiring board; and
the first wiring board and the second wiring board are electrically connected to each other via the electrode.

2. The semiconductor device as claimed in claim 1,
wherein the semiconductor element includes a semiconductor substrate and a semiconductor integrated circuit formed on the semiconductor substrate; and
the electrode is electrically connected to the semiconductor integrated circuit.

3. The semiconductor device as claimed in claim 1,
wherein one of a first pad and a first wiring pattern connected to an end part of the electrode is provided on the first surface of the semiconductor element facing the first wiring board; and
one of a second pad and a second wiring pattern connected to another end part of the electrode is provided on the second surface of the semiconductor element facing the second wiring board.

4. The semiconductor device as claimed in claim 1,
wherein the semiconductor element is flip-chip connected to the semiconductor element connection pad of the first wiring board.

5. The semiconductor device as claimed in claim 1,
wherein a second wiring board wiring pattern is provided on a surface of the second wiring board facing the semiconductor element;
an inside connection terminal is provided between the second wiring board wiring pattern provided on the surface of the second wiring board and one of a second pad and a second wiring pattern provided on the second surface of the semiconductor element; and
the second wiring board and the electrode are electrically connected to each other via the inside connection terminal.

6. The semiconductor device as claimed in claim 5,
wherein an electronic component connection pad electrically connected to the second wiring board wiring pattern provided on the second wiring board is provided on the second wiring board positioned at a side opposite to a side facing the semiconductor element; and
an electronic component is connected to the electronic component connection pad.

7. The semiconductor device as claimed in claim 1,
wherein sealing resin is provided so as to fill a gap between the first wiring board and the second wiring board.

8. The semiconductor device as claimed in claim 1,
wherein an outside connection pad electrically connected to the semiconductor element connection pad is provided on the first wiring board.

9. The semiconductor device as claimed in claim 1,
wherein the electrode is a piercing electrode configured to pierce the semiconductor element.

10. The semiconductor device as claimed in claim 1,
wherein the electrode is an end surface electrode provided on an end surface of the semiconductor element.

11. A semiconductor device, comprising:
a first wiring board having a semiconductor element connection pad;
a first semiconductor element electrically connected to the semiconductor element connection pad; and
at least one second semiconductor element stacked on the first semiconductor element, the second semiconductor element being electrically connected to the first semiconductor element; and
a second wiring board facing the first wiring board and the second semiconductor element, the second wiring board being electrically connected to the first wiring board;
wherein a first piercing electrode is provided in the first semiconductor element so as to pierce the first semiconductor element,
a second piercing electrode is provided in at least one second semiconductor element so as to pierce the second semiconductor element; and
the first wiring board and the second wiring board are electrically connected to each other via the first piercing electrode and the second piercing electrode.

12. A semiconductor device, comprising:
a first wiring board having a semiconductor element connection pad;
a first semiconductor element electrically connected to the semiconductor element connection pad; and
at least one second semiconductor element stacked on the first semiconductor element, the second semiconductor element being electrically connected to the first semiconductor element; and
a second wiring board facing the first wiring board and the second semiconductor element, the second wiring board being electrically connected to the first wiring board;
wherein a first end surface electrode is provided on an end surface of the first semiconductor element,
a second end surface electrode is provided on an end surface of the at least one second semiconductor element; and
the first wiring board and the second wiring board are electrically connected to each other via the first end surface electrode and the second end surface electrode.
